(19) United States
(12) Patent Application Publication
(10) Pub. No.: US 2026/0045932 A1
(43) Pub. Date: Feb. 12, 2026

(54) PASSBAND FILTER COMBINING RESONATORS OF A FIRST TYPE AND RESONATORS OF A SECOND TYPE

(71) Applicant: SKYWORKS SOLUTIONS, INC., Irvine, CA (US)

(72) Inventors: Yiliu Wang, Irvine, CA (US); Nan Wu, Irvine, CA (US); Joshua James Caron, Summerfield, NC (US)

(21) Appl. No.: 19/290,564

(22) Filed: Aug. 5, 2025

Related U.S. Application Data
(60) Provisional application No. 63/681,466, filed on Aug. 9, 2024.
(60) Provisional application No. 63/681,471, filed on Aug. 9, 2024.

(51) Int. Cl. H03H 9/56

(52) U.S. Cl. CPC H03H 9/566

(57) ABSTRACT

According to the present disclosure, an acoustic wave filter is provided. The acoustic wave filter has a pass band and is configured to filter a radio frequency signal. The acoustic wave filter comprises a series resonator and a shunt resonator, the shunt resonator having a primary mode defined by a resonant frequency of the shunt resonator and a secondary mode defined by a longitudinal mode of the shunt resonator, the primary mode defining a lower edge of the pass band and the secondary mode being of a higher frequency than the primary mode. A corresponding radio-frequency module and wireless mobile device comprising said acoustic wave filter are also provided.

### CROSS REFERENCE TO RELATED APPLICATIONS

This application claims priority under 35 U.S.C. § 119(e) to U.S. Provisional Patent Application Ser. No. 63/681,466, titled “PASSBAND FILTER COMBINING RESONATORS OF A FIRST TYPE AND RESONATORS OF A SECOND TYPE,” filed Aug. 9, 2024, and to U.S. Provisional Patent Application Ser. No. 63/681,471, titled “PASSBAND FILTER COMBINING RESONATORS OF A FIRST TYPE AND RESONATORS OF A SECOND TYPE,” filed Aug. 9, 2024, the entire content of each being incorporated herein by reference for all purposes.

### BACKGROUND

### Field

Aspects and embodiments disclosed herein relate to acoustic wave filters, such as for use in radio-frequency front end (RFFE) modules. Aspects and embodiments disclosed herein also relate to radio-frequency (RF) modules and wireless devices comprising said acoustic wave filters.

### Description of the Related Technology

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed.

Acoustic wave filters can be implemented in radio frequency electronic systems. For instance, filters in a radio frequency front end (RFFE) of a mobile phone can include acoustic wave filters. An acoustic wave filter can be a band pass filter. A plurality of acoustic wave filters can be arranged as a multiplexer. For example, two acoustic wave filters can be arranged as a duplexer. An acoustic wave filter with rejection over a relatively wide frequency range outside of a passband can be desirable. Designing such a filter can be challenging.

### SUMMARY

The innovations described in the claims each have several aspects, no single one of which is solely responsible for its desirable attributes. Without limiting the scope of the claims, some prominent features of this disclosure will now be briefly described.

According to a first aspect of this disclosure there is provided an acoustic wave filter having a pass band and configured to filter a radio frequency signal. The acoustic wave filter comprises a series resonator and a shunt resonator, the shunt resonator having a primary mode defined by a resonant frequency of the shunt resonator and a secondary mode defined by a longitudinal mode of the shunt resonator, the primary mode defining a lower edge of the pass band and the secondary mode being of a higher frequency than the primary mode.

In one example, the secondary mode enhances rejection at the lower edge of the pass band.

In one example, the secondary mode is enhanced.

In one example, the shunt resonator has a Q factor of one of less than 5,000, less than 2,000, or less than 1,000.

In one example, the shunt resonator is a surface acoustic wave resonator.

In one example, the shunt surface acoustic wave resonator comprises an interdigital transducer electrode and a pair of acoustic reflectors. A pitch of the pair of acoustic reflectors is the same as the pitch of the interdigital transducer electrode.

In one example, the shunt surface acoustic wave resonator comprises an interdigital transducer electrode and a pair of acoustic reflectors. A pitch of the pair of acoustic reflectors is narrower than the pitch of the interdigital transducer electrode.

In one example, the shunt surface acoustic wave resonator comprises an interdigital transducer electrode having gradation regions at either end of the interdigital transducer electrode. A pitch of the gradation regions is in a range of 1.0 to 1.1 times the pitch of the interdigital transducer electrode.

In one example, the shunt resonator is a multilayer piezoelectric substrate surface acoustic wave resonator.

In one example, the shunt resonator is a Lamb wave resonator.

In one example, the shunt resonator has a plurality of secondary modes, each of the secondary modes defined by a longitudinal mode of the shunt resonator and having a higher frequency than the primary mode.

In one example, the acoustic wave filter is a band pass filter.

In one example, the acoustic wave filter has a pass band corresponding to a fifth generation New Radio operating band.

In one example, the acoustic wave filter is a high pass filter.

In one example, the acoustic wave filter is a band stop filter.

In one example, the acoustic wave filter is a ladder filter.

In one example, the acoustic wave filter is a lattice filter.

In one example, the acoustic wave filter is a hybrid filter including a ladder filter component and a lattice filter component.

According to a second aspect of this disclosure there is provided a radio-frequency module. The radio-frequency module comprises a packaging substrate configured to receive a plurality of devices and a die mounted on the packaging substrate, the die including an acoustic wave filter having a pass band and configured to filter a radio frequency signal, the acoustic wave filter including a series resonator and a shunt resonator, the shunt resonator having a primary mode defined by a resonant frequency of the shunt resonator and a secondary mode defined by a longitudinal mode of the shunt resonator, the primary mode defining a lower edge of the pass band and the secondary mode being of a higher frequency than the primary mode.

According to a third aspect of this disclosure there is provided a wireless mobile device. The wireless mobile device comprises one or more antennas and a radio-frequency module that communicates with the one or more antennas, the radio-frequency module having a die including an acoustic wave filter having a pass band and configured to filter a radio frequency signal, the acoustic wave filter including a series resonator and a shunt resonator, the shunt resonator having a primary mode defined by a resonant frequency of the shunt resonator and a secondary mode defined by a longitudinal mode of the shunt resonator, the primary mode defining a lower edge of the pass band and the secondary mode being of a higher frequency than the primary mode.

According to a fourth aspect of this disclosure there is provided an acoustic wave filter having a stop band and configured to filter a radio frequency signal. The acoustic wave filter comprises a series resonator defining a lower edge of the stop band and a shunt resonator. The shunt resonator has a primary mode defined by a resonant frequency of the shunt resonator and a secondary mode defined by a longitudinal mode of the shunt resonator, the secondary mode being of a lower frequency than the first mode and the frequencies of both the primary mode and the secondary mode being within the stop band.

In one example, the primary mode and the secondary mode of the shunt resonator coincide with spurious resonant modes of the series resonator to enhance rejection in the stop band.

In one example, the secondary mode is enhanced.

In one example, the shunt resonator has a Q factor of less than 5,000, less than 2,000, or less than 1,000.

In one example, the shunt resonator is a surface acoustic wave resonator.

In one example, the shunt surface acoustic wave resonator comprises an interdigital transducer electrode and a pair of acoustic reflectors, and a pitch of the acoustic reflectors is the same as the pitch of the interdigital transducer electrode.

In one example, the shunt surface acoustic wave resonator comprises an interdigital transducer electrode and a pair of acoustic reflectors, and a pitch of the acoustic reflectors is less than the pitch of the interdigital transducer electrode.

In one example, the shunt surface acoustic wave resonator comprises an interdigital transducer electrode having gradation regions at either end of the interdigital transducer electrode, and a pitch of the gradation region is in the range of 1.0 to 1.1 times the pitch of the interdigital transducer electrode.

In one example, the shunt resonator is a multilayer piezoelectric substrate surface acoustic wave resonator.

In one example, the shunt resonator is a Lamb wave resonator.

In one example, the shunt resonator has a plurality of secondary modes, each of the secondary modes defined by a longitudinal mode of the shunt wave resonator and of a lower frequency than the first mode.

In one example, the acoustic wave filter is a band pass filter.

In one example, the acoustic wave filter has a pass band corresponding to a fifth generation New Radio operating band.

In one example, the acoustic wave filter is a low pass filter.

In one example, the acoustic wave filter is a band stop filter.

In one example, the acoustic wave filter is a ladder filter.

In one example, the acoustic wave filter is a lattice filter.

In one example, the acoustic wave filter is a hybrid filter comprising a ladder filter component and a lattice filter component.

According to a fifth aspect of this disclosure there is provided a radio-frequency module. The radio frequency module comprises a packaging substrate configured to receive a plurality of devices and a die mounted on the packaging substrate. The die has an acoustic wave filter having a stop band and configured to filter a radio frequency signal, the acoustic wave band pass filter including a series resonator defining a lower edge of the stop band, and a shunt resonator, the shunt resonator having a primary mode defined by a resonant frequency of the shunt resonator and a secondary mode defined by a longitudinal mode of the shunt resonator, the secondary mode being of a lower frequency than the first mode and the frequencies of both the primary mode and the secondary mode being within the stop band.

According to a sixth aspect of this disclosure there is provided a wireless mobile device. The wireless mobile device comprises one or more antennas and a radio-frequency module that communicates with the one or more antennas, the radio-frequency module having a die including an acoustic wave filter having a stop band and configured to filter a radio frequency signal, the acoustic wave band pass filter including a series resonator defining a lower edge of the stop band, and a shunt resonator, the shunt resonator having a primary mode defined by a resonant frequency of the shunt resonator and a secondary mode defined by a longitudinal mode of the shunt resonator, the secondary mode being of a lower frequency than the first mode and the frequencies of both the primary mode and the secondary mode being within the stop band.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

Still other aspects, embodiments, and advantages of these exemplary aspects and embodiments are discussed in detail below. Aspects or embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the aspects and embodiments disclosed herein. In the figures, each identical or nearly identical component that is illustrated in various figures is represented by a like numeral. For purposes of clarity, not every component may be labeled in every figure. In the figures:

FIG. 1A is a comparison of a frequency response of the admittance of a resonator according to aspects and embodiments disclosed herein;

FIG. 1B is a comparison of a frequency response of the insertion loss of a resonator according to aspects and embodiments disclosed herein;

FIG. 2A is a comparison of a frequency response of band pass filter according to aspects and embodiments disclosed herein;

FIG. 2B is a comparison of a frequency response of band pass filter according to aspects and embodiments disclosed herein;

FIG. 3A is a comparison of a frequency response of band pass filter according to aspects and embodiments disclosed herein;

FIG. 3B is a comparison of a frequency response of band pass filter according to aspects and embodiments disclosed herein;

FIG. 4 is a plan schematic of a SAW resonator according to aspects and embodiments disclosed herein;

FIG. 5 is a cross-sectional schematic of a SAW resonator according to aspects and embodiments disclosed herein;

FIG. 6 is an illustration of a pitch profile of a SAW resonator according to aspects and embodiments disclosed herein;

FIG. 7 is a cross-sectional schematic of a Lamb wave resonator according to aspects and embodiments disclosed herein;

FIG. 8 is a cross-sectional schematic of a multilayer piezoelectric substrate SAW resonator according to aspects and embodiments disclosed herein;

FIG. 9 illustrates an example of a ladder filter according to aspects and embodiments disclosed herein;

FIG. 10 illustrates an example of a lattice filter according to aspects and embodiments disclosed herein;

FIG. 11 illustrates an example of a hybrid filter according to aspects and embodiments disclosed herein;

FIG. 12 is a schematic diagram of a radio frequency module according to aspects and embodiments disclosed herein; and

FIG. 13 is a schematic of a wireless device according to aspects and embodiments disclosed herein.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Aspects and embodiments described herein are directed to an acoustic wave filter, such as for use in radio-frequency front end RFFE modules, having an improved out of band rejection.

Acoustic wave filters are comprised of a plurality of resonators arranged in different configurations to achieve the desired properties, such as a pass band with a particular frequency range, a given level of out of band rejection, and so on. Typically, resonators, such as SAW resonators, have a resonant frequency (also called a first mode or primary mode) that is used to provide some or all of the desired properties of the filter. For example, in a ladder band pass filter, the resonant frequency of a shunt resonator is typically used to define the lower edge of the pass band.

As well as the resonant frequency, resonators will have other modes that exhibit some amount of resonance, often termed spurious modes or secondary modes. Longitudinal modes in a SAW resonator are an example of such spurious modes. Usually, when designing acoustic wave filters, the spurious modes of resonators in the acoustic wave filter are considered a problem as they interfere with the desired properties of the acoustic wave filter. Resonators for use in acoustic wave filters are usually designed to suppress the spurious modes of the resonators to minimize their effect on the properties of acoustic wave filters that they are used in.

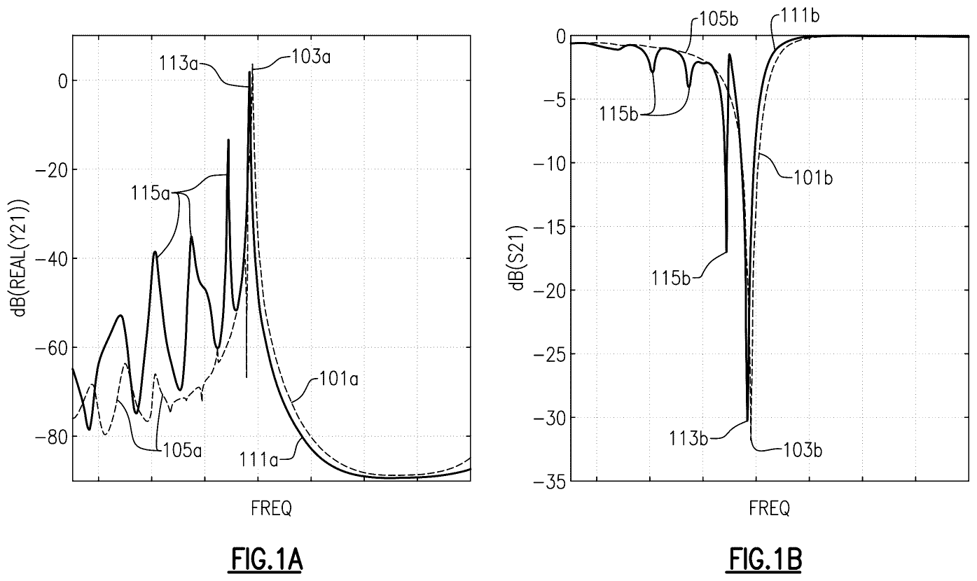

FIGS. 1A and 1B illustrate a frequency response of an example of a SAW resonator with suppressed longitudinal (i.e., spurious) modes. The admittance of a SAW resonator with suppressed longitudinal modes is illustrated by line 101a in FIG. 1A and the insertion loss of a SAW resonator with suppressed longitudinal modes is illustrated by line 101b in FIG. 1B. As can be seen, the resonant frequency of the resonator is illustrated by peak 103a in FIG. 1A and trough 103b in FIG. 1B. Some minor spurious modes of the resonator are evident in peaks 105a of FIG. 1A but are highly suppressed in FIG. 1B as can be seen in region 105b.

However, it has been appreciated by the inventors listed on this application that the spurious modes of resonators can, in fact, be utilized to improve the performance of acoustic wave filters, and that the spurious modes can be enhanced to further improve the performance of acoustic wave filters.

FIGS. 1A and 1B also illustrate the frequency response of a SAW resonator with enhanced longitudinal modes. The admittance of a SAW resonator with enhanced longitudinal modes is illustrated by line 111a in FIG. 1A and the insertion loss of a SAW resonator with enhanced longitudinal modes is illustrated by line 111b in FIG. 1B. As can be seen, the resonant frequency of the resonator is illustrated by peak 113a in FIG. 1A and trough 113b in FIG. 1B.

As can be seen by comparing peaks 103a and 113a, as well as troughs 103b and 113b, the resonance of both the SAW resonator with suppressed longitudinal modes and the SAW resonator with enhanced longitudinal modes are very similar. However, the enhanced spurious modes can be seen by comparing peaks 115a with peaks 105a and troughs 115b with region 105b. The SAW resonator with enhanced longitudinal modes displays a much larger resonant response at each longitudinal mode than the SAW resonator with suppressed longitudinal modes.

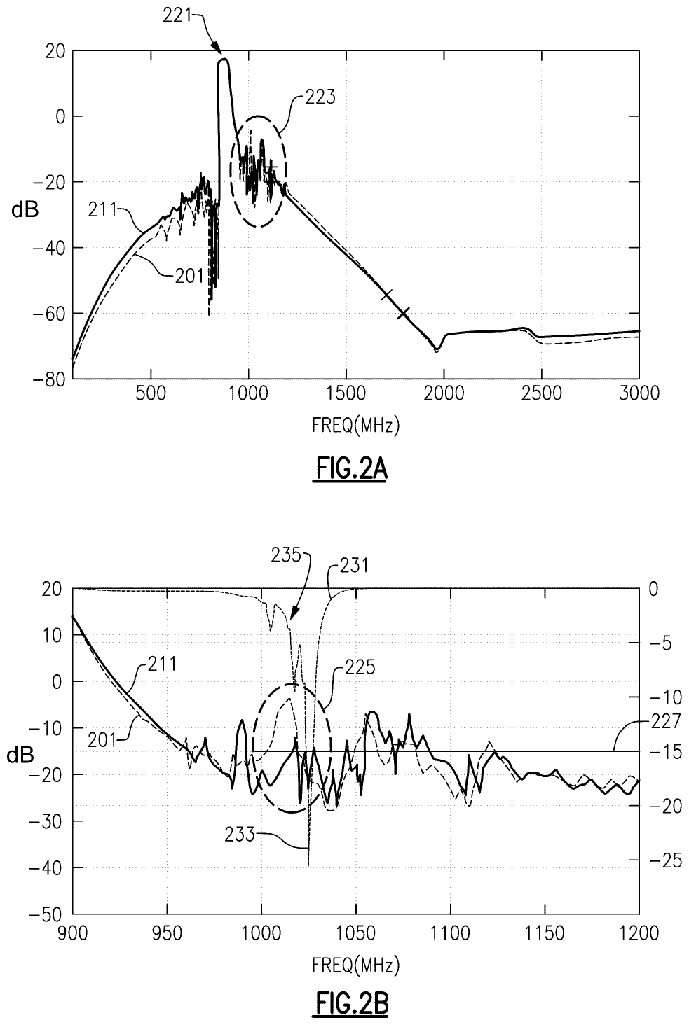

A resonator with unsuppressed (e.g., enhanced) longitudinal modes can be integrated into an acoustic wave filter to enhance out of band rejection, as illustrated in FIGS. 2A and 2B. Line 201 in FIGS. 2A and 2B illustrate the attenuation of signals of a typical band pass filter. As can be seen, a pass band 221 is evident and signals of frequency within the pass band are passed by the acoustic wave filter, which in this case is a band pass filter. Outside of the pass band 221 (out of band, or in the stop band) signals are heavily attenuated. FIG. 2B illustrates the region 223 of FIG. 2A in more detail, with line 227 illustrating a desired out of band attenuation. As can be seen, in region 225 of FIG. 2B, the response of the band pass filter, line 201, is well above the desired attenuation level 227.

To improve the out of band rejection in region 225, an additional shunt resonator with unsuppressed (e.g., enhanced) spurious modes can be introduced into the acoustic wave filter. The frequency response of the additional shunt resonator (in this case the insertion loss) is shown by line 231 in FIG. 2B and is superimposed with line 201. The resonant frequency 233 of the additional shunt resonator can be chosen so that the resonant frequency 233 as well as the enhanced spurious modes 235 span the region where additional attenuation is desired (i.e., region 225).

The frequency response of an acoustic wave filter including this additional shunt resonator is shown in FIGS. 2A and 2B by line 211. Looking at FIG. 2A, it can be seen that the additional shunt resonator has minimal impact on the pass band 221 of the acoustic wave filter. However, looking at region 225 of FIG. 2B, it can be seen that the attenuation of the acoustic wave filter in region 225 is improved and is now substantially below the desired attenuation level 227.

While using an additional resonator having suppressed spurious modes would provide some improvement in the attenuation of an acoustic wave filter in region 225, the use of a resonator having enhanced spurious modes 235 provides broader suppression, meaning that fewer additional resonators may be used to achieve the desired effect.

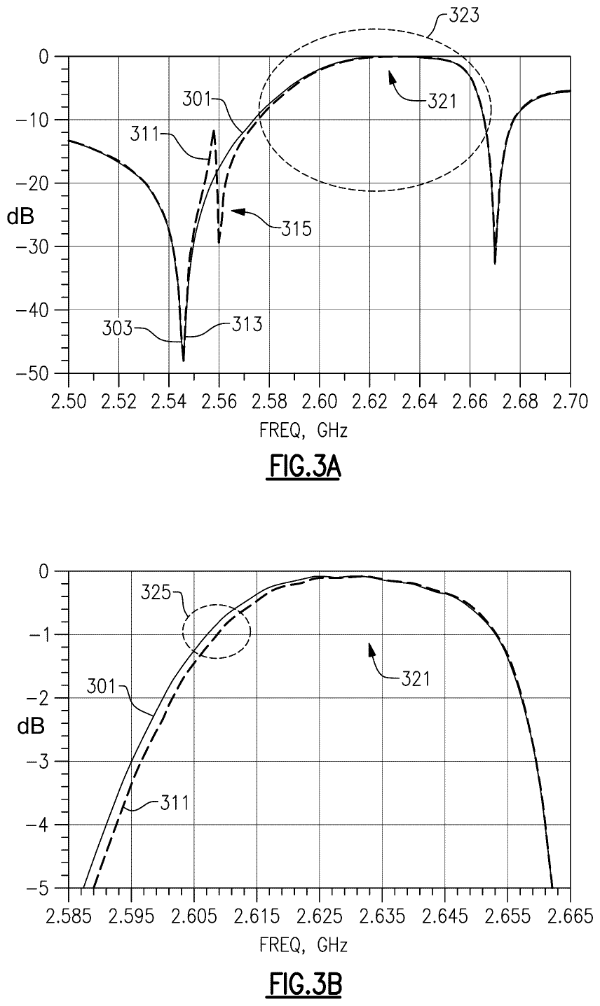

Shunt resonators having unsuppressed spurious modes can also be used as shunt resonators defining the edge of a pass band, as described below with respect to FIGS. 3A and 3B.

FIG. 3A illustrates a frequency response of a typical band pass acoustic wave filter with line 301, with the pass band 321 clearly identifiable. The lower edge of the pass band is defined by the resonant frequency 301 of a shunt resonator having suppressed spurious modes. FIG. 3A also illustrates a frequency response of a band pass acoustic wave filter with line 311 that replaces the shunt resonator with suppressed spurious modes that defines the lower edge of the pass band with a shunt resonator with unsuppressed (e.g., enhanced) spurious modes 315.

From FIG. 3A, it can be seen that at frequencies below about 2.56 GHz line 311 is above line 301, i.e., the unsuppressed spurious modes lead to reduced attenuation. However, above about 2.56 GHz, an improvement in attenuation can be observed, and typically this region is of greater interest, especially as even the peak of line 311 due to the spurious modes remains at greater than 10 dB of attenuation. The range of most interest, region 323, is illustrated in more detail in FIG. 3B.

FIG. 3B shows how the use of a shunt resonator with unsuppressed (e.g., enhanced) spurious modes rather than a shunt resonator with suppressed spurious modes can improve the out of band rejection at the lower edge of the pass band. As can be seen, above around 2.625 GHz, lines 301 and 311 are substantially coincident. However, below around 2.625 GHz, e.g., in region 325, line 311 drops more quickly than line 301, with around an additional 0.2 dB of attenuation at region 325 and around an additional 0.4 dB of attenuation at the far left of the graph.

Switching the shunt resonator that defines the low frequency edge of the pass band of an acoustic wave filter from one with suppressed spurious modes to one with unsuppressed (e.g., enhanced) spurious modes can, therefore, provide improved out of band rejection and allow the fine tuning of the edge of the pass band without the inclusion of any additional resonators in the acoustic wave filter.

The spurious modes of various types of filter can be utilized as described above. In particular, SAW resonators can be used.

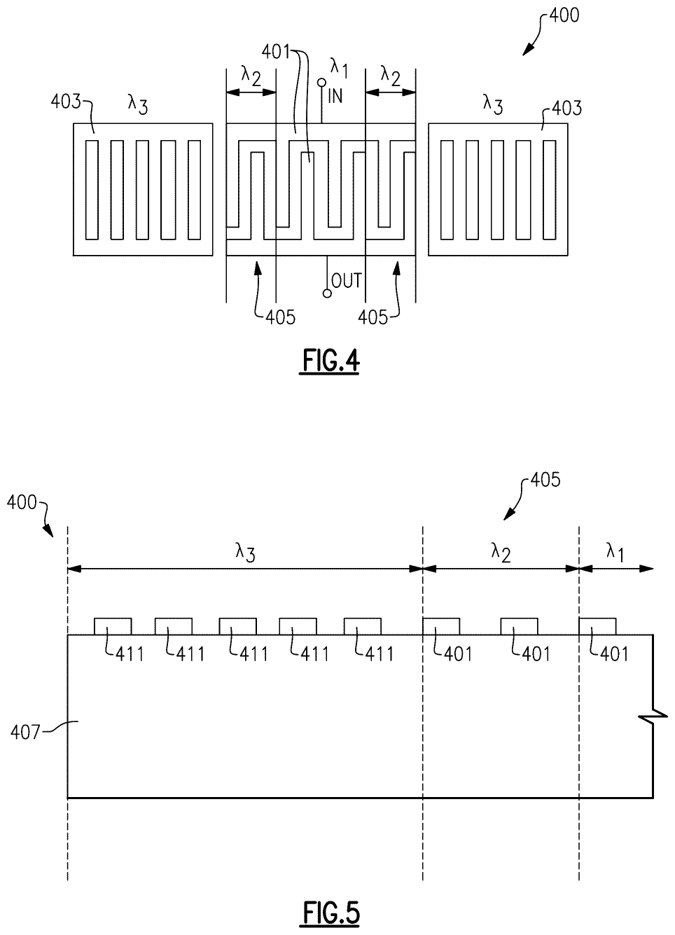

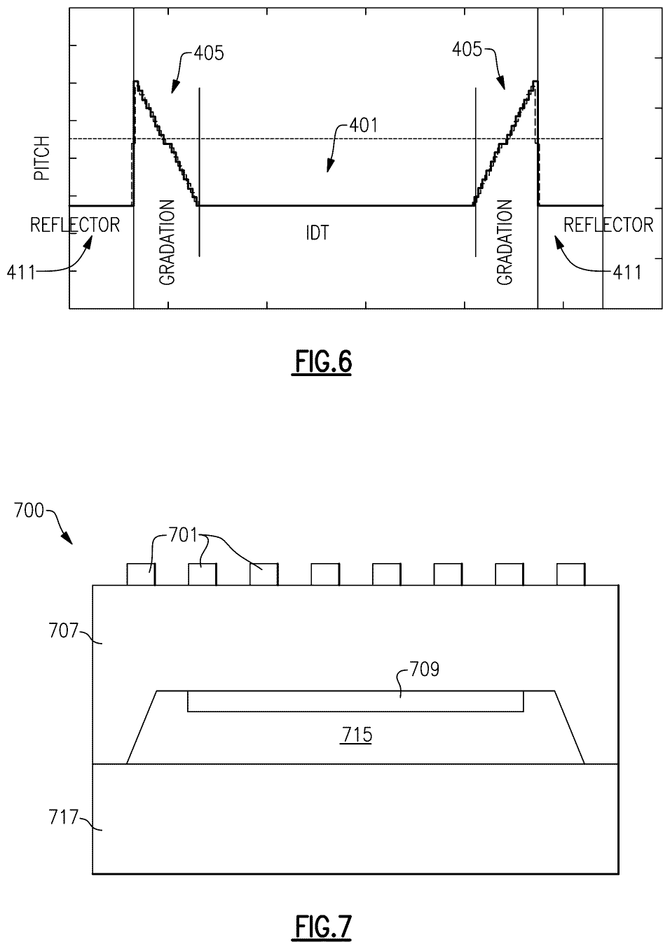

FIG. 4 illustrates a top plan view of a SAW resonator 400 configured to have enhanced spurious modes. FIG. 5 is a diagram of a cross-section of one end of SAW resonator 400 as shown in FIG. 4. FIG. 6 illustrates a pitch profile of SAW resonator 400 as shown in FIGS. 4 and 5. The SAW resonator 400 is an example of an acoustic wave resonator. The SAW resonator 400 is an example of a non-temperature compensated SAW resonator, though it is understood that the principles disclosed herein may also be applied to temperature compensated SAW resonators. SAW filters disclosed herein can include any suitable number of SAW resonators 400.

As shown in FIG. 4, SAW resonator 400 includes an interdigital transductor (IDT) electrode 401 and a pair of acoustic reflectors 403. At either end of the IDT electrode 401, next to the acoustic reflectors 403, the IDT electrode 401 comprises a pair of gradation regions 405.

As shown in FIG. 5, the illustrated SAW resonator 400 includes a piezoelectric material layer 407 with the IDT electrode 401 and the acoustic reflector 411 on the piezoelectric material layer 407. The piezoelectric material layer 407 can be a lithium niobate layer or a lithium tantalate layer, for example.

As shown in FIG. 4, the IDT electrode 401 has a pitch of λ₁ between the gradation regions 405 and a pitch of λ₂ in the gradation regions 405, and the pitch of the acoustic reflectors 411 is λ₃. The acoustic reflector 411 pitch λ₃ may be the same as the IDT electrode 401 pitch λ₁, or the acoustic reflector 411 pitch λ₃ may be less than the IDT electrode 401 pitch λ₁. That is to say, λ₁≥λ₃. The gradation region 405 pitch λ₂ may be the same as the IDT electrode 401 pitch λ₁, or the gradation region 405 pitch λ₂ may be greater than the IDT electrode 401 pitch λ₁. That is to say, λ₂≥λ₁. In particular, the gradation region 405 pitch λ₂ may be in the range of 1.0-1.1 times the pitch λ₁ of the IDT electrode 401. That is to say, λ₁≤λ₂≤1.1*λ₁. Such an arrangement of pitches across the portions of the SAW resonator can act to advantageously enhance the spurious modes.

Another resonator that can be used in acoustic wave filters as described above is a Lamb wave resonator.

FIG. 7 is a diagram of a cross-section of a Lamb wave resonator 700 according to an embodiment. Acoustic wave filters disclosed herein can include any suitable number of Lamb wave resonators 700. As illustrated, the Lamb wave resonator 700 includes a piezoelectric material layer 707, an IDT electrode 701 on the piezoelectric material layer 707, and an electrode 709. The piezoelectric material layer 707 can be a thin film. The piezoelectric material layer 707 can be an aluminum nitride layer. In other instances, the piezoelectric material layer 707 can be any suitable piezoelectric material layer. For example, the piezoelectric material layer 707 can be a lithium niobate layer or a lithium tantalate layer. The electrode 709 and the IDT electrode 701 are on opposing sides of the piezoelectric material layer 707. The electrode 709 can be grounded in certain instances. In some other instances, the electrode 709 can be floating. An air cavity 715 is disposed between the electrode 709 and a substrate 717. Any suitable cavity can be implemented in place of the air cavity 715. The substrate 717 can be a semiconductor substrate. For example, the substrate 717 can be a silicon substrate. The substrate 717 can be any other suitable substrate, such as a quartz substrate, a sapphire substrate, or a spinel substrate.

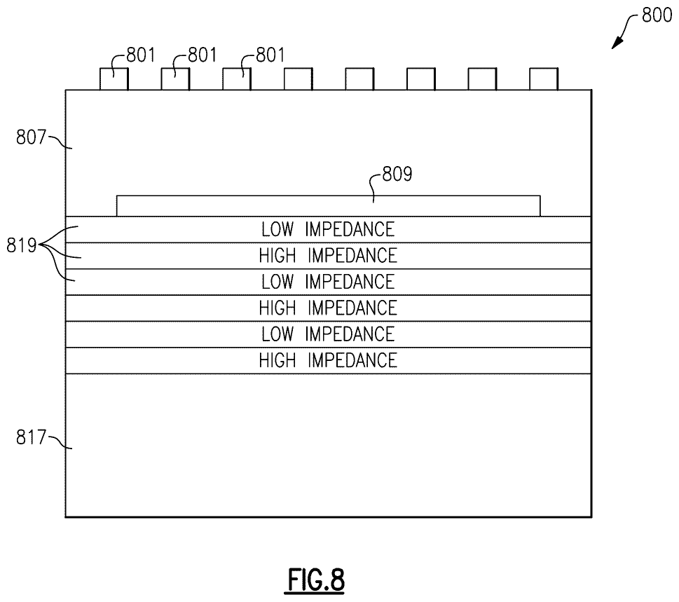

FIG. 8 is a diagram of a cross-section of a solidly mounted Lamb wave resonator 800 according to an embodiment. Acoustic wave filters disclosed herein can include any suitable number of solidly mounted Lamb wave resonators 800. As illustrated, the solidly mounted Lamb wave resonator 800 includes an electrode 809, a piezoelectric material layer 807, an IDT electrode 801 on the piezoelectric material layer 807, and a Bragg reflector 819 located between the substrate 817 and the electrode 809. The Bragg reflector 819 includes alternating low impedance and high impedance layers. As an example, the Bragg reflector 819 can include alternating silicon dioxide layers and tungsten layers. Any other suitable Bragg reflector can alternatively or additionally be included in the solidly mounted Lamb wave resonator 800. In the solidly mounted Lamb wave resonator 800, the piezoelectric material layer 807 can be an aluminum nitride layer, for example.

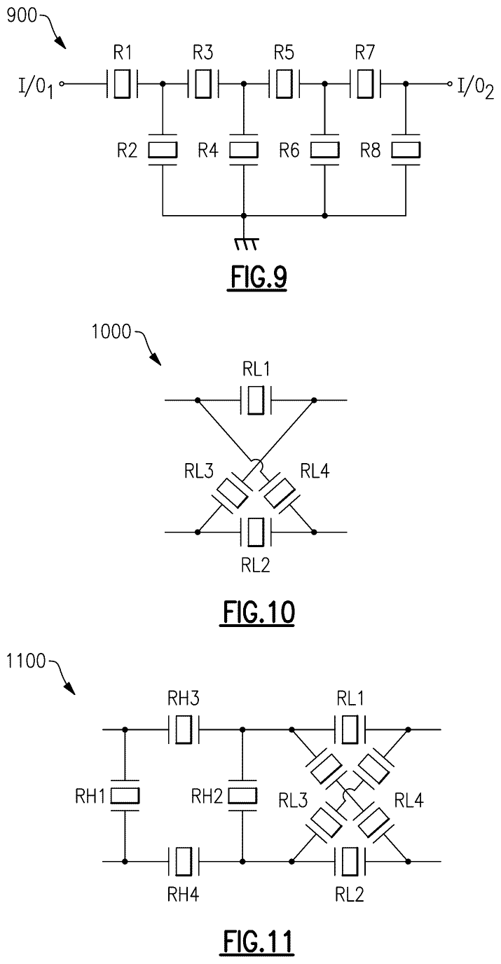

Acoustic wave devices disclosed herein can be implemented in a variety of different filter topologies. Example filter topologies include without limitation, ladder filters, lattice filters, hybrid ladder lattice filters, notch filters where a notch is created by the resonant frequency of a shunt resonator, hybrid acoustic and non-acoustic inductor-capacitor filters, and the like. Some such filters can be band pass filters. In some other examples, such filters include band stop filters. In some instances, acoustic wave devices disclosed herein can be implemented in filters with one or more other types of resonators and/or with passive impedance elements, such as one or more inductors and/or one or more capacitors. Some example filter topologies will now be discussed with reference to FIGS. 9 to 11. Any suitable combination of features of the filter topologies of FIGS. 9 to 11 can be implemented together with each other and/or with other filter topologies.

FIG. 9 is a schematic diagram of a ladder filter 900 that includes an acoustic wave resonator according to an embodiment. The ladder filter 900 is an example topology that can implement a band pass filter formed from acoustic wave resonators. In a band pass filter with a ladder filter topology, the shunt resonators can have lower resonant frequencies than the series resonators. The ladder filter 900 can be arranged to filter a radio frequency signal. As illustrated, the ladder filter 900 includes series acoustic wave resonators R1, R3, R5, and R7 and shunt acoustic wave resonators R2, R4, R6, and R8 coupled between a first input/output port I/O₁ and a second input/output port I/O₂. Any suitable number of series acoustic wave resonators can be included in a ladder filter. Any suitable number of shunt acoustic wave resonators can be included in a ladder filter. The first input/output port I/O₁ can be a transmit port and the second input/output port I/O₂ can be an antenna port. Alternatively, the first input/output port I/O₁ can be a receive port and the second input/output port I/O₂ can be an antenna port.

One or more of the shunt acoustic wave resonators of the ladder filter 900, i.e., resonators R2, R4, R6, and R8, can include an acoustic wave resonator having unsuppressed or enhanced spurious modes, as described above, to provide improved out of band rejection.

FIG. 10 is a schematic diagram of a lattice filter 1000 that includes an acoustic wave resonator according to an embodiment. The lattice filter 1000 is an example topology that can form a band pass filter from acoustic wave resonators. The lattice filter 1000 can be arranged to filter an RF signal. As illustrated, the lattice filter 1000 includes acoustic wave resonators RL1, RL2, RL3, and RL4. The acoustic wave resonators RL1 and RL2 are series resonators. The acoustic wave resonators RL3 and RL4 are shunt resonators. The illustrated lattice filter 1000 has a balanced input and a balanced output.

One or more of the shunt acoustic wave resonators of the lattice filter 1000, i.e., resonators RL3 and RL4, can include an acoustic wave resonator having unsuppressed or enhanced spurious modes, as described above, to provide improved out of band rejection.

FIG. 11 is a schematic diagram of a hybrid ladder and lattice filter 1100 that includes an acoustic wave resonator according to an embodiment. The illustrated hybrid ladder and lattice filter 1100 includes series acoustic resonators RL1, RL2, RH3, and RH4 and shunt acoustic resonators RL3, RL4, RH1, and RH2. The hybrid ladder and lattice filter 1100 includes one or more acoustic wave resonators in accordance with any suitable principles and advantages disclosed herein.

One or more of the shunt resonators of the hybrid ladder and lattice filter 1100, i.e., resonators RL3, RL4, RH1, and RH2, can include an acoustic wave resonator having unsuppressed or enhanced spurious modes, as described above, to provide improved out of band rejection.

According to certain examples, an acoustic wave resonator in accordance with any suitable principles and advantages disclosed herein can be included in a filter that also includes one or more inductors and/or one or more capacitors.

One or more acoustic wave resonators including any suitable combination of features disclosed herein be included in a filter arranged to filter a radio frequency signal in a fifth generation (5G) New Radio (NR) operating band within Frequency Range 1 (FR1). A filter arranged to filter a radio frequency signal in a 5G NR operating band can include one or more acoustic wave resonators with unsuppressed or enhanced spurious modes as disclosed herein. FR1 can be from 410 megahertz (MHz) to 7.125 gigahertz (GHz), for example, as specified in a current 5G NR specification. One or more acoustic wave resonators in accordance with any suitable principles and advantages disclosed herein can be included in a filter arranged to filter a radio frequency signal in a fourth generation (4G) Long Term Evolution (LTE) operating band. One or more acoustic wave resonators in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) application. One or more acoustic wave resonators in accordance with any suitable principles and advantages disclosed herein can be included in an acoustic wave filter for high frequency bands, such as frequency bands above 3 gigahertz (GHz) and/or frequency bands above 5 GHz within FR1. A filter with an acoustic wave resonator as disclosed herein can be used for a 5G NR band with a relatively wide passband.

The acoustic wave resonators disclosed herein can be implemented in a standalone filter and/or in a filter in any suitable multiplexer. Such filters can be any suitable topology, such as any filter topology of FIGS. 9 to 11. The filter can be a band pass filter arranged to filter a 4G LTE band and/or 5G NR band.

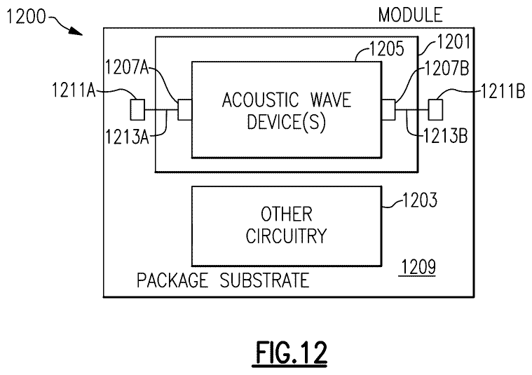

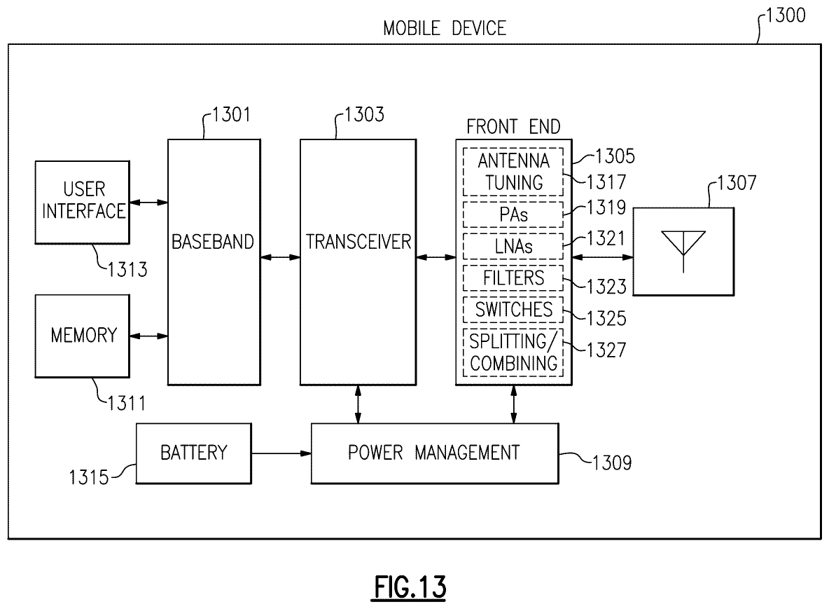

FIG. 12 is a schematic diagram of a radio frequency module 1200 that includes an acoustic wave component 1201 according to an embodiment. The illustrated radio frequency module 1200 includes the acoustic wave component 1201 and other circuitry 1203. The acoustic wave component 1201 can include one or more acoustic wave devices in accordance with any suitable combination of features of the acoustic wave resonators and filters disclosed herein. The acoustic wave component 1201 can include an acoustic wave filter that includes a plurality of acoustic wave resonators, for example.

The acoustic wave component 1201 shown in FIG. 12 includes one or more acoustic wave devices 1205 and terminals 1207A and 1207B. The one or more acoustic wave devices 1205 include at least one acoustic wave device implemented in accordance with any suitable principles and advantages disclosed herein. The terminals 1207A and 1207B can serve, for example, as an input contact and an output contact. Although two terminals are illustrated, any suitable number of terminals can be implemented for a particular implementation. The acoustic wave component 1201 and the other circuitry 1203 are on the same packaging substrate 1209 in FIG. 12. The package substrate 1209 can be a laminate substrate. The terminals 1207A and 1207B can be electrically connected to contacts 1211A and 1211B, respectively, on the packaging substrate 1209 by way of electrical connectors 1213A and 1213B, respectively. The electrical connectors 1213A and 1213B can be bumps or wire bonds, for example.

The other circuitry 1203 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. The other circuitry 1203 can be electrically connected to the one or more acoustic wave devices 1205. The radio frequency module 1200 can include one or more packaging structures to, for example, provide protection and/or facilitate easier handling of the radio frequency module 1200. Such a packaging structure can include an overmold structure formed over the packaging substrate 1209. The overmold structure can encapsulate some or all of the components of the radio frequency module 1200.

The acoustic wave devices disclosed herein can be implemented in wireless communication devices. FIG. 13 is a schematic block diagram of a wireless communication device 1300 that includes one or more acoustic wave filters or acoustic wave resonators according to the disclosure above. The wireless communication device 1300 can be a mobile device. The wireless communication device 1300 can be any suitable wireless communication device. For instance, a wireless communication device 1300 can be a mobile phone, such as a smart phone. As illustrated, the wireless communication device 1300 includes a baseband system 1301, a transceiver 1303, a front end system 1305, one or more antennas 1307, a power management system 1309, a memory 1311, a user interface 1313, and a battery 1315.

The wireless communication device 1300 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 1303 generates RF signals for transmission and processes incoming RF signals received from the antennas 1307. Various functionalities associated with the transmission and receiving of RF signals can be achieved by one or more components that are collectively represented in FIG. 13 as the transceiver 1303. In one example, separate components (for instance, separate circuits or dies) can be provided for handling certain types of RF signals.

The front end system 1305 aids in conditioning signals provided to and/or received from the antennas 1307. In the illustrated embodiment, the front end system 1305 includes antenna tuning circuitry 1317, power amplifiers (PAs) 1319, low noise amplifiers (LNAs) 1321, filters 1323, switches 1325, and signal splitting/combining circuitry 1327. However, other implementations are possible. The filters 1323 can include one or more acoustic wave filters that include any suitable number of acoustic wave devices in accordance with any suitable principles and advantages disclosed herein.

For example, the front end system 1305 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 1300 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 1307 can include antennas used for a wide variety of types of communications. For example, the antennas 1307 can include antennas for transmitting and/or receiving signals associated with a wide variety of frequencies and communications standards.

In certain implementations, the antennas 1307 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 1300 can operate with beamforming in certain implementations. For example, the front end system 1305 can include amplifiers having controllable gain and phase shifters having controllable phase to provide beam formation and directivity for transmission and/or reception of signals using the antennas 1307. For example, in the context of signal transmission, the amplitude and phases of the transmit signals provided to the antennas 1307 are controlled such that radiated signals from the antennas 1307 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 1307 from a particular direction. In certain implementations, the antennas 1307 include one or more arrays of antenna elements to enhance beamforming.

The baseband system 1301 is coupled to the user interface 1313 to facilitate processing of various user input and output (I/O), such as voice and data. The baseband system 1301 provides the transceiver 1303 with digital representations of transmit signals, which the transceiver 1303 processes to generate RF signals for transmission. The baseband system 1301 also processes digital representations of received signals provided by the transceiver 1303. As shown in FIG. 13, the baseband system 1301 is coupled to the memory 1311 of facilitate operation of the wireless communication device 1300.

The memory 1311 can be used for a wide variety of purposes, such as storing data and/or instructions to facilitate the operation of the wireless communication device 1300 and/or to provide storage of user information.

The power management system 1309 provides a number of power management functions of the wireless communication device 1300. In certain implementations, the power management system 1309 includes a PA supply control circuit that controls the supply voltages of the power amplifiers 1319. For example, the power management system 1309 can be configured to change the supply voltage(s) provided to one or more of the power amplifiers 1319 to improve efficiency, such as power added efficiency (PAE).

As shown in FIG. 13, the power management system 1309 receives a battery voltage from the battery 1315. The battery 1315 can be any suitable battery for use in the wireless communication device 1300, including, for example, a lithium-ion battery.

Although some of principles disclosed herein are described in relation to SAW filters and/or resonators, any suitable principles and advantages disclosed herein can be applied to other types of acoustic wave devices that include an IDT electrode, such as Lamb wave devices and/or boundary wave devices. For example, any suitable combination of features of the acoustic velocity adjustment structures disclosed herein can be applied to a Lamb wave device and/or a boundary wave device.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to. ” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as,” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An acoustic wave filter having a pass band and configured to filter a radio frequency signal, the acoustic wave filter comprising:
a series resonator; and
a shunt resonator, the shunt resonator having a primary mode defined by a resonant frequency of the shunt resonator and a secondary mode defined by a longitudinal mode of the shunt resonator, the primary mode defining a lower edge of the pass band and the secondary mode being of a higher frequency than the primary mode.

2. The acoustic wave filter of claim 1 wherein the secondary mode enhances rejection at the lower edge of the pass band.

3. The acoustic wave filter of claim 1 wherein the secondary mode is enhanced.

4. The acoustic wave filter of claim 1 wherein the shunt resonator has a Q factor of one of less than 5,000, less than 2,000, or less than 1,000.

5. The acoustic wave filter of claim 1 wherein the shunt resonator is a surface acoustic wave resonator.

6. The acoustic wave filter of claim 5 wherein the shunt surface acoustic wave resonator comprises an interdigital transducer electrode and a pair of acoustic reflectors, a pitch of the pair of acoustic reflectors being a same pitch as a pitch of the interdigital transducer electrode.

7. The acoustic wave filter of claim 5 wherein the shunt surface acoustic wave resonator comprises an interdigital transducer electrode and a pair of acoustic reflectors, a pitch of the pair of acoustic reflectors being narrower than a pitch of the interdigital transducer electrode.

8. The acoustic wave filter of claim 5 wherein the shunt surface acoustic wave resonator comprises an interdigital transducer electrode having gradation regions at either end of the interdigital transducer electrode, a pitch of the gradation regions being in a range of 1.0 to 1.1 times a pitch of the interdigital transducer electrode.

9. The acoustic wave filter of claim 5 wherein the shunt resonator is a multilayer piezoelectric substrate surface acoustic wave resonator.

10. The acoustic wave filter of claim 1 wherein the shunt resonator is a Lamb wave resonator.

11. The acoustic wave filter of claim 1 wherein the shunt resonator has a plurality of secondary modes, each of the secondary modes defined by a longitudinal mode of the shunt resonator and having a higher frequency than the primary mode.

12. The acoustic wave filter of claim 1 wherein the acoustic wave filter is a band pass filter.

13. The acoustic wave filter of claim 12 wherein the acoustic wave filter has a pass band corresponding to a fifth generation New Radio operating band.

14. The acoustic wave filter of claim 1 wherein the acoustic wave filter is a high pass filter.

15. The acoustic wave filter of claim 1 wherein the acoustic wave filter is a band stop filter.

16. The acoustic wave pass filter of claim 1 wherein the acoustic wave filter is a ladder filter.

17. The acoustic wave filter of claim 1 wherein the acoustic wave filter is a lattice filter.

18. The acoustic wave filter of claim 1 wherein the acoustic wave filter is a hybrid filter including a ladder filter component and a lattice filter component.

19. A radio-frequency module comprising:
a packaging substrate configured to receive a plurality of devices; and
a die mounted on the packaging substrate, the die including an acoustic wave filter having a pass band and configured to filter a radio frequency signal, the acoustic wave filter including a series resonator and a shunt resonator, the shunt resonator having a primary mode defined by a resonant frequency of the shunt resonator and a secondary mode defined by a longitudinal mode of the shunt resonator, the primary mode defining a lower edge of the pass band and the secondary mode being of a higher frequency than the primary mode.

20. An acoustic wave filter having a stop band and configured to filter a radio frequency signal, the acoustic wave filter comprising:
a series resonator defining a lower edge of the stop band; and
a shunt resonator, the shunt resonator having a primary mode defined by a resonant frequency of the shunt resonator and a secondary mode defined by a longitudinal mode of the shunt resonator, the secondary mode being of a lower frequency than the primary mode and the frequencies of both the primary mode and the secondary mode being within the stop band.
